(19) United States
(12) Patent Application Publication
(10) Pub. No.: US 2007/0184633 A1
(43) Pub. Date: Aug. 9, 2007

(54) METHOD OF SEGMENTING WAFER

(76) Inventor: Chen-Hsiung Yang, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/459,933

(22) Filed: Jul. 25, 2006

(30) Foreign Application Priority Data
Feb. 7, 2006 (TW) 095104121

(51) Int. Cl. H01L 21/00

(52) U.S. Cl. 438/460; 257/E21.238

(57) ABSTRACT

A wafer is provided and a front scribe line pattern is defined on a front surface of the wafer. A back scribe line pattern corresponding to the front scribe line pattern is defined on a back surface of the wafer. Then the wafer is attached to an extendable film and a wafer breaking process is performed to form a plurality of dies by virtue by extending the extendable film.

### BACKGROUND OF THE INVENTION

1. Field of the Invention

The invention is related to a method of segmenting a wafer, and more particularly to a method of segmenting a wafer without damaging the structure layer disposed on the front surface of the wafer.

2. Description of the Prior Art

Micro-electromechanical systems (MEMS) devices, such as pressure sensors or microphones, have more complicated mechanically designed structures than conventional devices, for instance, hanged membrane structures, and require a double-semiconductor sided process for manufacturing. However, the steps of double-sided processing are complex and may face lots of difficulties. For example, the hanged membrane structures have fragile structures that fracture easily when a segmenting process is performed. In addition, the front structure of the wafer can be damaged easily when a back process is performed.

Generally, the segmenting process of the MEMS devices is performed to divide the wafer into a plurality of dies by a cutting blade after the front process and the back process are accomplished. However, using the cutting blade to perform the segmenting process may result in the following problems:
(1) The minimum width of the cutting blade is about 100 micrometer (μm). As the size of the devices is reduced, the integration of the wafer will be affected by the width of the scribe line.
(2) The process cycle lengthens as the integration of the wafer increases. This will affect the production yield.
(3) Using the cutting blade may result in a great number of particles. Therefore, a cleaning solution is provided to perform a cleaning process. However, some fragile hanged membrane structures may be fractured during the cleaning process.

The segmenting process of the prior art may use an etching process as well as the cutting blade. Please refer to FIG. 1 to FIG. 3. FIG. 1 to FIG. 3 are schematic diagrams illustrating a method of a segmenting process performed by an etching process according to prior art. As shown in FIG. 1, a wafer 10 is provided, and a sacrificial layer 12 and a structural layer 14 are formed on a front surface of the wafer 10. Accordingly, a photoresist pattern 16 is formed on the surface of the structural layer 14 and functions as a hard mask to perform an etching process that defines front scribe lines 18 on the front surface of the wafer 10.

As shown in FIG. 2, the photoresist pattern 16 is removed. The wafer 10 is overturned, and the structural layer 14 is attached to a supporting wafer 22 by a piece of tape 20. Afterward, another photoresist pattern 24 is formed on a back surface of the wafer and functions as a mask to perform a dry etch process that defines a back scribe line 26 and a cavity 28 of MEMS devices. As shown in FIG. 3, the photoresist pattern 24 is removed and a wet etching process is performed to remove the sacrificial layer 12 so that a hanged membrane structure 30 is formed.

Since the wet etch process is performed to remove the sacrificial layer 12, the etching solution easily erodes the structural layer 14 and damages the hanged membrane structures 30 via the back scribe line 26. In addition, the hanged membrane structures 30 may fracture due to the stress resulting from the tape 20.

### SUMMARY OF THE INVENTION

The primary objective of the present invention is to provide a method of segmenting a wafer that prevents the structural layer on the front surface of the wafer from being damaging.

To obtain this objective, a method of segmenting a wafer is provided. At first, a wafer is provided and a front scribe line pattern is defined on a front surface of the wafer. Then a back scribe line pattern corresponding to the front scribe line is defined. The wafer is attached to an extendable film and a wafer breaking process is performed to form a plurality of dies by virtue of extending the extendable film.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 are schematic diagrams illustrating a method of segmenting process performed by an etching process according to the prior art.

FIG. 4 through FIG. 10 are schematic diagrams illustrating a method of segmenting a wafer according to a preferred embodiment of the invention.

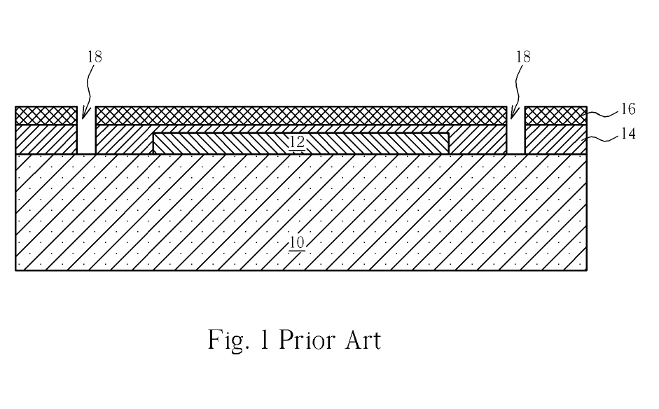

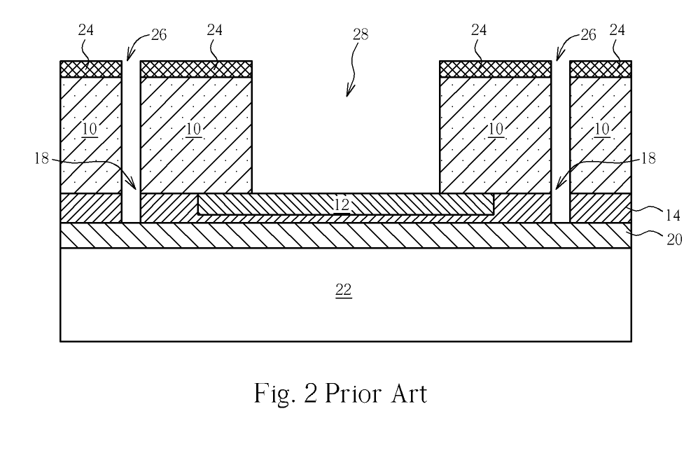

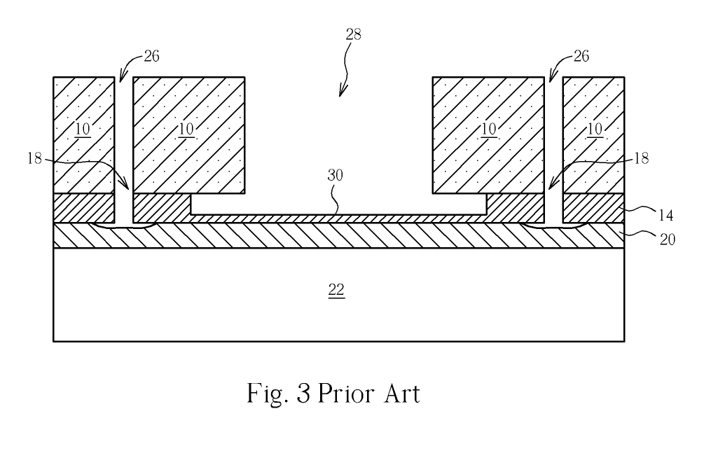

### DETAILED DESCRIPTION

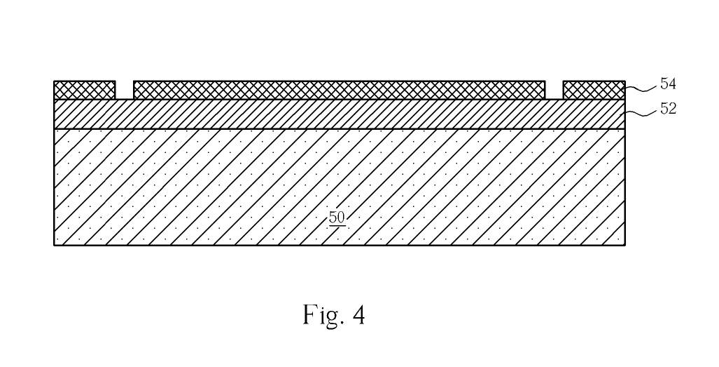

Please refer to FIG. 4 through FIG. 10. FIG. 4 through FIG. 10 are schematic diagrams illustrating a method of segmenting a wafer according to a preferred embodiment of the invention. As shown in FIG. 4, a wafer 50 is provided. The wafer 50 has a structural layer 52 on a front surface thereof. The structural layer 52 may have different construction depending on the device to be formed. This embodiment is illustrated as fabricating device having hanged membrane structure. The structural layer 52 may further comprises a sacrificial layer (not shown). However, the structural layer 52 may also be manufactured as a MEMS device structural layer or a semiconductor device layer. After that, a front mask pattern 54 is formed on the surface of the structural layer 52. The front mask pattern 54 has a plurality of openings to define the accurate positions of front scribe lines. The substance of the front mask pattern 54 may be a dielectric material, such as silicon oxide and silicon nitride, an organic material, or a photoresist.

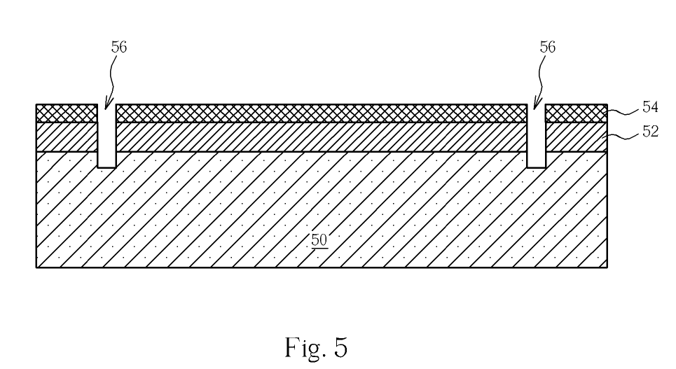

As shown in FIG. 5, an etching process is performed on the structural layer 52 via the front mask pattern 54 to define a front scribe line pattern 56. A wet etch process or a dry etch process is applicable depending on the etching effect. The front scribe line pattern 56 passes through the structural layer 52 and reaches the wafer 50. The wafer 50 has a greater thickness than a depth of the front scribe line pattern 56. The depth of the front scribe line pattern 56 may be modified depending on the thickness of the wafer 50.

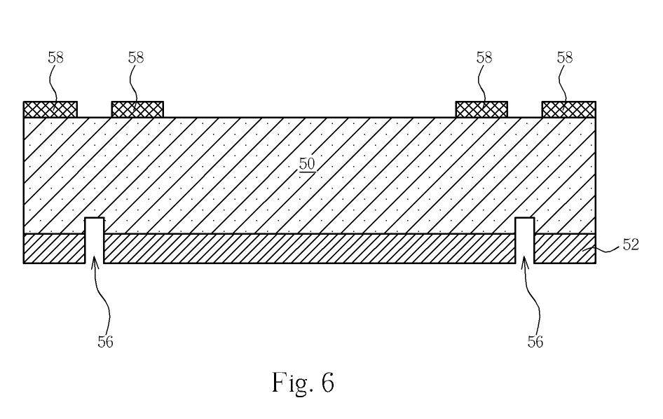

As shown in FIG. 6, the front mask pattern 54 is removed immediately. Then the wafer 50 is overturned and a back mask pattern 58 is formed on a back surface of the wafer 50. A part of the back mask pattern 58 corresponding to the front mask pattern 54 defines the position of a back scribe line pattern corresponding to the front scribe line pattern 56. The back mask pattern 58 further comprises an opening to define a cavity for exposure of the structural layer 52 by a subsequent etching process. The substance of the front mask pattern 58 may be a dielectric material, such as silicon oxide and silicon nitride, an organic material, or a photoresist.

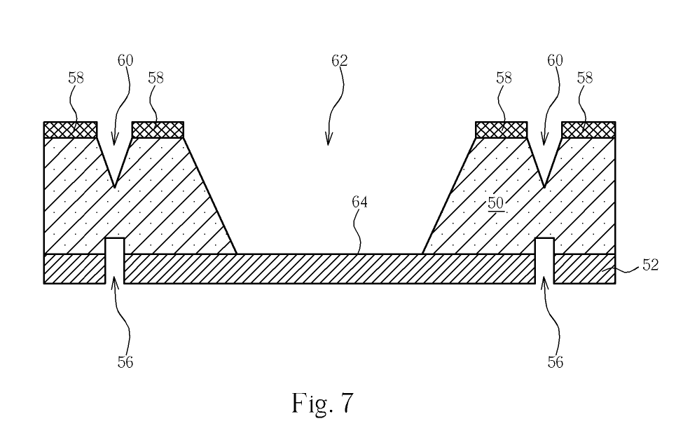

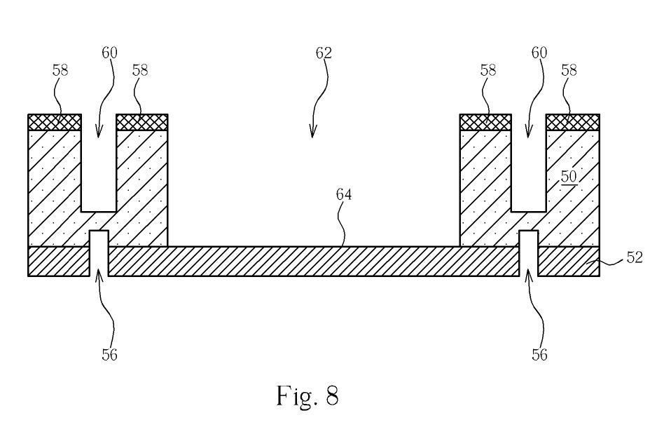

As shown in FIG. 7, an etching process is performed to etch the wafer 50 via the opening of the back mask pattern 58 that defines a back scribe line pattern 60 corresponding to the front scribe line pattern 56 on the back surface of the wafer 50. A cavity 62 that exposes the structural layer 52 is formed as well in the etching process to form a hanged membrane structure 64. An anisotropic wet etch process is performed to etch the silicon wafer 50, and therefore, both the back scribe line pattern 60 and the cavity 62 have inclined inside walls. The etching solution may be a potassium hydroxide (KOH) solution, an ethylenediamine-pyrocatechol-water (EDP) solution, or a tetramethyl ammonium hydroxide (TMAH) solution. However, a dry etch process is allowable, such as a plasma etching, to define the back scribe line pattern 60 and the cavity 62. As shown in FIG. 8, in a case where the dry etch process is selected, both the back scribe line pattern 60 and the cavity 62 have vertical inside walls. In addition, adjusting aspect ratio may allow the back scribe line pattern 60 to have a smaller depth than a thickness of the wafer 50. However, the cavity 62 may have a greater depth that reaches the structural layer 52.

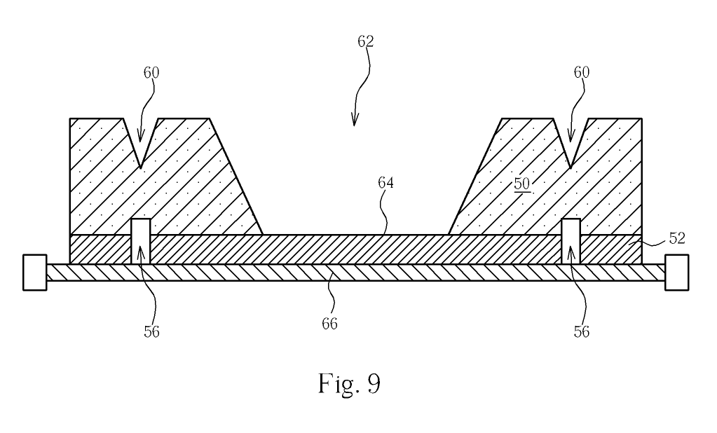

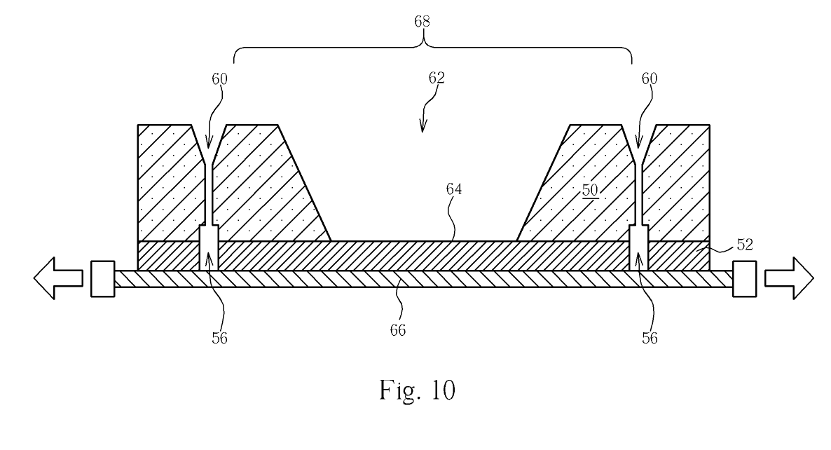

As shown in FIG. 9, the back mask pattern 58 is removed, and the wafer 50 is attached to an extendable film 66. In this embodiment, the front surface of the wafer 50 is attached to the extendable film 66. However, attaching the back surface of the wafer 50 to the extendable film 66 is allowable. As shown in FIG. 10, a wafer breaking process is performed by virtue of extending the extendable film 66 to divide the wafer 50 along the front scribe line pattern 56 and the back scribe line pattern 60, thereby forming a plurality of dies 68. Therefore, the method of segmenting a wafer is finished.

According to the above embodiment, the method of the invention performs the etching process upon the front surface and the back surface of the wafer respectively. Then the wafer breaking process is performed to segment the wafer. Therefore the method of segmenting the wafer has the advantages of high density and automation, and therefore can increase the production of the dies. Additionally, the front scribe line pattern does not intersect the back scribe line pattern before the wafer breaking process is performed. Consequently, this may prevent the structural layer from erosion and damages resulting from the etching solution of the back-sided wet etch process. Moreover, the step of defining the back scribe line pattern is integrated into the step of defining the cavities. The production cost will not be raised. Furthermore, there is no protecting layer laid over the structural layer on the front surface of the wafer. For that reason, the problem of damaging the structural layer resulting from the stress is solved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of segmenting wafer comprising:
providing a wafer;
defining a front scribe line pattern on a front surface of the wafer;
defining a back scribe line pattern corresponding to the front scribe line pattern on a back surface of the wafer; and
attaching the wafer to an extendable film and performing a wafer breaking process to form a plurality of dies by virtue of extending the extendable film.

2. The method of claim 1, wherein defining the front scribe line pattern comprises:
defining a front mask pattern comprising a plurality of openings on the front surface of the wafer;
etching the front surface of the wafer via the openings to define the front scribe line pattern; and
removing the front mask pattern.

3. The method of claim 1, wherein defining the back scribe line pattern comprises:
defining a back mask pattern comprising a plurality of openings on the back surface of the wafer;
etching the back surface of the wafer via the openings to define the back scribe line pattern; and
removing the back mask pattern.

4. The method of claim 3, wherein a dry etch process is performed to etch the back surface of the wafer.

5. The method of claim 3, wherein a wet etch process is performed to etch the back surface of the wafer.

6. The method of the claim 1, wherein the front surface of the wafer is attached to the extendable film to perform the wafer breaking process.

7. A method of segmenting wafer comprising:
providing a wafer comprising a structural layer on a front surface thereof;
defining a front scribe line pattern on the structural layer, the wafer having a thickness greater than a depth of the front scribe line pattern;
performing an etching process to define a back scribe line pattern corresponding to the front scribe line pattern on a back surface of the wafer, and to form a plurality of cavities exposing the structural layer and a plurality of hanged membrane structures; and
attaching the wafer to an extendable film, and accordingly performing a wafer breaking process by virtue of extending the extendable film to break the wafer and form a plurality of dies.

8. The method of claim 7, wherein defining the front scribe line pattern comprises:
defining a front mask pattern comprising a plurality of openings on the front surface of the wafer;
etching the front surface of the wafer via the openings to define the front scribe line pattern; and
removing the front mask pattern.

9. The method of claim 7, wherein defining the back scribe line pattern and the hanged membrane structures comprises the following steps:
defining a back mask pattern comprising a plurality of openings on the back surface of the wafer;
etching the back surface of the wafer via the openings to define the back scribe line pattern and the hanged membrane structures ; and
removing the back mask pattern.

10. The method of claim 9, wherein a dry etch process is performed to etch the back surface of the wafer.

11. The method of claim 9, wherein a wet etch process is performed to etch the back surface of the wafer.

12. The method of the claim 9, wherein the front surface of the wafer is attached to the extendable film to perform the wafer breaking process.
